(19) United States
(12) Patent Application Publication
(10) Pub. No.: US 2005/0193942 A1
(43) Pub. Date: Sep. 8, 2005

(54) Method for making substrate wafers for low-defect semiconductor components, obtained thereby and uses thereof

(76) Inventors: Claudio Gorgoni, Orbe (CH); Burkhardt Speit, Mainz (DE); Ingo Koehler, Ingelheim (DE); Jaques Guinchard, Giez (CH); Peter Blaum, Weiterstadt (DE); Wolfram Beier, Essenheim (DE)

Correspondence Address: STRIKER, STRIKER & STENBY, 103 EAST ENCK ROAD, HUNTINGTON, NY, 11743, US

(21) Appl. No.: 11/069,117

(22) Filed: Mar. 1, 2005

(30) Foreign Application Priority Data
Mar. 3, 2004 (DE) 10 2004 010 377.1

(51) Int. Cl. C30B 1/00; C30B 15/00

(52) U.S. Cl. 117/3; 117/13; 117/26

(57) ABSTRACT

A method for making a substrate wafer for a low-defect semiconductor component is described. In this method a single crystal having a [0001] surface perpendicular to a c-axis thereof is formed, subdivided into thin disks each with at least one disk surface to be coated, the at least one disk surface is smoothed and the thin disks are tempered at a temperature above 1770 K. Preferably the tempering occurs for at least 10 minutes at temperatures greater than 1770 K in a dust-poor atmosphere with a reduced oxygen partial pressure. Al₂O₃ is a preferred material for the single crystal.

### BACKGROUND OF THE INVENTION

1. Field of the Invention

The present invention relates to substrates and/or wafers for making low-defect and/or fault-free, electronic semiconductor components, especially III-V semiconductor functioning layers, methods for making them and their use as well as semiconductor components, which contain this sort of substrate.

2. Related Art

Electronic components, especially those with III-V nitride semiconductor engineering, have attained ever-increasing importance, above all for high temperature and high-power electronics, in the manufacture of HL lasers and in the manufacture of high-intensity light emitted diodes, the so-called LEDs, which are manufactured in large scale production. Currently there are no suitable substrate and/or wafer materials, which have high transparency and suitable thermal properties, available for development of these components, especially with GaN. These substrate and/or wafer materials should have sufficient thermal conductivity, thermal expansion and shape stability up to temperatures greater than 1470 K. Also there should be no mismatch between the crystal lattices of the substrate and the crystalline GaN layer. Sapphire (Al₂O₃) is a suitable substrate, which approaches GaN and its semiconductor materials, such as AlN, InGaN, AlGaN or InN, in its physical properties.

For large scale manufacture of this type of component sapphire crystals must be obtainable at a reasonable price.

The Czochralski growth method is a technique used for electronic component applications. A crystallographically oriented material structure is obtained by this growth method. A method of this sort, for example, is described in the unpublished DE-A 103 06 801.5 filed by the applicants responsible for the present invention. Usually the sapphire crystal is grown in oblong crystals along its crystallographic c-axis, which is perpendicular to the [0001] surface. The crystals have a diameter of about less than 5 to 15 cm. In this way a product with rotationally symmetric stress distribution is obtained. Subsequently nearly stress-free crystals can be obtained by subsequently tempering in a tempering process above 1750 K. Also growth processes along a direction inclined at 600 to the c-axis are known.

The single crystal so obtained is then comminuted into thin wafer disks, for example by sawing. These wafers act as substrates and/or as supporting materials for semiconductor layers and are suitably smoothed, especially by polishing and lapping and/or grinding, prior to further processing. New mechanical stresses produced in the crystal by these processing steps should be removed at least on one surface prior to further processing of the wafer, for example by epitaxy. Intrinsic stresses present in the material of the thin wafer, which usually has a thickness of less than 0.6 mm, partially relax in the coating process between 1070 K and 1370 K and lead to larger deformation. This sort of deformation of the wafer leads to impairment of the component performance (interfering growth) and to finished products with large yield losses during further processing. For this reason the wafer is subjected to tempering at temperatures up to about 1770 K after lapping or grinding in order to relax the above-described increased stresses during manufacture of electronic components. Tempering is no longer possible after a final polishing, since deformations of the polished substrate surface at high temperatures must be considered and/or impurities in the tempering atmosphere prefer to deposit on the substrate surface and can bind to it.

It has now been shown that growth defects arising from deposition of hetero-epitaxial semiconductor layers and semiconductor layer packets, such as nanopipes, pin holes and hilogs. Nanopipe structures, [E. Valcheva, T. Paskova, A. Persson and B. Monemar, “Nanopipes in Thick GaN Films Grown at High Growth Rate”, Phys. Stat. Sol. (a) 194, no. 2002, pp. 532-535], lead, for example, to greatly reduced light yields in LEDs by radiationless energy conversion.

Nanopipes have a hollow tubular core region with a diameter of less than 1 micron. These tubules can continue through the entire applied semiconductor layer, which comprises several different partial layers as required, and influence the material properties and/or layer sensitivity. In order to reduce formation of this sort of artifact, the growth parameters, such as the growth rate and the epitaxy temperature are optimized. An existing nanopipe can no longer grow, i.e. its upper end is closed. The position, at which a nanopipe opens out on the surface, is called the “pit”.

A mismatch between the substrate material and the semiconductor layer applied to it is probably the cause of this sort of defect [J. Kang, T. Ogawa, “Materials in Nanopipes of Undoped GaN”, J. Mater. Res., Vol. 14, No. 1, January (1999)]. Furthermore surface impurities and out-gassing of material are discussed as possible causes. Up to now it has not been possible to produce LED layers without a noteworthy number of growth defects. Interference microscopy is an effective standard method for determining defects in surfaces.

### SUMMARY OF THE INVENTION

An object of the present invention is to provide electronic components, which are poorer in growth defects produced by crystallographic defects, especially pin holes, nanopipes and/or pits and hilogs, than currently known electronic elements.

This object is attained by the features defined in the appended claims.

It was surprisingly found that semiconductor layers can be deposited, in which the deposited layer material does not contain growth errors on the substrate surface (so-called pits), when the supporting substrate disk or the wafer is tempered after a first especially mechanical working step of the surface to be coated, if necessary after lapping and/or grinding.

The tempering step according to the invention is preferably performed prior to the final polishing and prior to purification of the substrate. The tempering according to the invention is performed above 1770 K. Preferred tempering temperatures amount to at least 1790 K, especially at least 1820 K, wherein at least 1870 K and/or 1920 K are especially preferred. If especially outstanding results are to be obtained, in individual cases minimum tempering temperatures of 1970 K and/or 2020 K and even up to 2070 K have proven to be appropriate. However for many applications tempering at temperatures above 1770 K has proven to be sufficient. The upper temperature limit for these tempering steps is the temperature at which the substrate does not soften, i.e. under the melting point of 2310 K. A preferred upper limit amounts to 2170 K. An upper limit of 2120 K and especially at most 2070 are especially preferred. Because of the procedure according to the invention it is possible to obtain semiconductor products, which have only a few and/or no growth defects, such as nanopipes and pinholes in the form of pits on the substrate surface, and/or even are completely free of them. They have an upper limit for the number of growth defects on their surfaces of 10⁴/cm², preferably 10³/cm² and especially preferably 10²/cm², as determined by testing via interference microscopy (Leica Interference Microscopy, 160-power (16×10) magnification, resolution at most 0.8 microns). The determination of the growth defects is preferably performed without chemical or mechanical treatment of the semiconductor surfaces, e.g. by etching.

It is also possible to obtain semiconductor products, which have less than 10 growth defects per square centimeter and especially preferably less than 5 and/or at most 2-3 defects per cm² as determined by examination with an interference microscope. By the special procedure according to the invention it is possible without more to obtain products, which have no growth defects on their surfaces that are detectable with an interference microscope.

Crystals with a hexagonal lattice structure, which preferably have a [0001] surface and a crystallographic c-axis perpendicular to it, are especially preferred as substrates according to the invention. Sapphire and/or Al₂O₃ are especially suitable as substrate material. The formation of this sort of crystal structure is known. Preferably they are obtained with a Czochralski method. A suitably oriented cooled crystal seed is immersed in an Al₂O₃ melt and is slowly withdrawn from it. Preferably the crystal is drawn along its c-axis, which is perpendicular to the [0001] surface. The crystal so obtained is usually tempered in its entirety in order to reduce stress in the single crystal.

A crystal suitable for the method according to the invention is preferably made according to the Czochralski method so that an axial temperature gradient of at least 30 K/cm is set up in the δphase region (about 1 cm into the crystal from the melt). With that sort of gradient growth speeds of at least 40 mm/day are attained. Subsequently the single crystal is subjected to a temperature treatment in a radially symmetric temperature gradient, which is preferably as small as possible, with an axial gradient, which is as small as possible.

The crystal is preferably grown in the direction of the crystallographic c-axis. It has been shown that the growth preferably should occur with a deviation of less than 5° from the direction of the c-axis. Especially the deviation should be less than 2.5°. However generally the crystal should be grown in the crystallographic c-direction as exactly as possible.

The shape of the phase boundary between the crystal and the liquid melt is influenced by the drawing speed, the temperature gradient, which occurs in the first centimeter of the crystal, computed from the phase boundary and finally by the rotation speed. The shape of the phase boundary is preferably adjusted so that the phase boundary surface is convex in relation to the melt. The phase boundary surface usually has a radius of at least 0.05 m, but a radius of at least 0.2 m is preferred.

It has been shown that hexagonal single crystals can be grown especially rapidly with the above-described method features so that the drawing speed of at least 30 mm/day, especially at least 40 mm/day, is possible. In many cases a maximum drawing speed of 200 mm/day has proven suitable. Generally however a maximum of 150 mm/day, especially a maximum of 130 mm/day, is preferred, but a maximum of 120 mm/day is an especially preferred maximum growth rate.

The temperature treatment and/or tempering can be performed after the growth process in an after-heating region in the apparatus above the growth vessel. The single crystal may simply be brought into this after-heating region. It has proven to be advantageous when the single crystal is treated in a temperature treatment at a treatment temperature of at least 1750 K and/or isothermally for a time interval of at least one hour, preferably of at least two hours.

Preferably during the growth of the crystal the axial temperature gradient is adjusted so that it is in the direction of crystallographic c-axis and amounts to 30 K/cm in the crystal in the vicinity of the phase boundary surface, i.e. within the first centimeter between the phase boundary and the already finished crystal. Preferred values are at least 35 K/cm and especially at least 40 K/cm, but 50 K/cm is most preferred of these values. An especially preferred maximum gradient amounts to 200 K/cm, especially 150 K/cm.

Of course no entirely low-stress single crystals may be produced by these temperature gradients, but the stress state is completely uniform and radially symmetric. According to the invention stresses can be nearly eliminated isotropically in relation to the c-axis by a subsequent tempering process in a temperature range 200 to 500 K lower than used in the growth process at about 2320 K in a small axial and/or radial temperature gradient.

In this procedure a constant rotationally symmetric and/or axial temperature gradient should be maintained over the entire length of the single crystal at least in the temperature treatment of the crystal in a growth apparatus or in subsequent processing. This constant temperature gradient reduces anisotropic stress states in the single crystal.

The temperature can be varied linearly and/or step-wise during the temperature treatment and/or in tempering in a preferred special embodiment. A pause can occur during stepwise change of the temperature, for example at a phase transition of the metastable states δ and K to the thermodynamically stable Δ-form of the sapphire, e.g. at 1400±25 K and/or 1000±25 K. The pause preferably lasts for at least one hour, especially two hours.

An additional embodiment of the method is characterized by the performance of a two-step temperature treatment and of course with a first treatment step, in which the single crystal is cooled with a first cooling rate from a first treatment temperature, and with a second treatment step, in which the single crystal or a product produced from the single crystal is cooled with a smaller second cooling rate from a second treatment temperature. That the first and more rapid but controlled cooling is followed by a second treatment step, in which the cooling is slower, has proven to be very significant.

The single crystal can be cooled isothermally in the first treatment step in the after-heating region. This may be simply affected after making the single crystal.

In a preferred embodiment the single crystal is cooled after growing it in the growth oven at a first treatment step with a cooling rate of preferably at most 50 K per hour, especially less than 20 K per hour. With this comparatively rapid but controlled cooling the stresses in the already comparatively low-stress single crystal may be further reduced in a subsequent second treatment step.

The first treatment temperature or also the single treatment temperature in a one-step method, amounts preferably to 2100 K. Especially the variation of this temperature is at most ±50 K. The stress states relax especially well at this temperature.

In the second treatment step the single crystal should be cooled with a cooling rate of less than 15 K per hour. This slower cooling takes into consideration the larger volume of a complete crystal in comparison to a wafer of thickness less than 1 mm and assists in the formation of a largely stress-free single crystal without deformation effects.

After making and cooling the single crystal so obtained is subdivided into thin disks for blanks and of course preferably along the [0001] plane of the single crystal. The thickness of these disks usually amounts to less than 2 mm, wherein at most 1.5 mm, especially at least 1 mm is preferred. In many cases the substrate or wafer blanks with a thickness of at most 0.8 mm are preferred, but a wafer thickness of at most 0.7 mm or 0.6 mm is especially preferred. In many cases a wafer thickness of 0.5 mm has proven to be sufficient. The minimal thickness of this wafer usually amounts to at least 0.1 mm, wherein at least 0.2 mm and especially at least 0.3 mm is especially preferred. In many cases the wafers with a minimal thickness of at least 0.4 mm have proven to be suitable. The thin disk or wafer blanks so obtained are tested or examined with respect to their geometry and crystal orientation and if necessary erroneously oriented blanks are sorted out, after the subdividing, which usually happens by sawing.

After that the disk-blanks are further processed mechanically preferably by grinding and/or lapping and polishing. Lapping is understood to mean a surface smoothing, in which the surface is treated with a mechanical abrasive material with a free loose grain of a size of greater than 5 Πm. For this purpose a particulate especially with a grain size D91 is used. A grain size of D91 means that a grain distribution of grains or particles under 91 Πm diameter is guaranteed by sieving with a sieve with a mesh size of 91 Πm, i.e. the grains with a diameter greater than 9 Πm are excluded from the particulate. During polishing the surface is treated mechanically with similar loose free grinding bodies or grains with a size of less than 5-0.1 Πm. Thus in this case single grains with diameters above 5 Πm are not present in the polishing material. Diamond grain distributions of less than 5 Πm are considered for use, which have a maximum size of 5 Πm, and are obtained by sedimentation, sieving or other suitable fractionation methods.

Up to now it has been assumed that no tempering at high temperatures above 1770 K is possible after mechanical lapping, since at these temperatures a very large number of rejections of the surfaces and/or wafers is to be expected, which is caused by intrinsic stresses. However the tempering of the wafer disks according to the invention is possible either after grinding/lapping and before mechanical polishing or after grinding/lapping and after mechanical polishing, however prior to most chemical-mechanical polishing processes (CMP processes), in which the wafer disks are treated with loose silicate colloids with a grain size of less than 0.1 Πm. These types of colloids are designed for the desired particle sizes and are commercially obtainable. The determination of the grain diameter usually occurs by light scattering measurements according to known methods.

The tempering according to the invention is preferably performed so that the [0001] surface, which also provides the surface of the blank, is perpendicular or vertical. The oven itself is preferably an oven, which can be supplied with a gas mixture, whose heating chamber can be evacuated if necessary. The tempering according to the invention of course can be performed in principle with normal air at atmospheric pressure, but preferably occurs in an atmosphere with a reduced oxygen partial pressure. This may be attained by a protective gas atmosphere, e.g. argon or nitrogen, or also by producing a vacuum. The tempering is preferably performed in a reduced oxygen partial pressure of at most 10⁻¹⁰ mbar, but an oxygen partial pressure of 10⁻² to 10⁻⁶ mbar, especially 10⁻²-10⁻³ mbar, is particularly preferred.

The tempering itself is performed according to the invention until the fault and defect sites are removed. The required time interval may be established by one skilled in the art without more by means of simple experiments and depends also on the level of the temperature. Tempering times of at least 10 minutes have proven suitable. Preferred tempering times amount to at least 30 minutes, but minimum tempering times of one or 2 hours are preferred. Minimum tempering times of three hours are particularly preferred, wherein tempering times of four hours have proven especially suitable in many cases. Tempering times of greater than four hours have no significant additional effect, i.e. measurable additional influence, on the material performance. It is preferred to perform the tempering according to clean room class 100.000 (ISO 14644-1/2 or FS 209E) in a dust-free environment. In a suitable embodiment of the invention the tempering is performed in a dust-tight box, preferably in boxes made from noble metal.

Although has been shown that heating speed during tempering is comparatively uncritical, heating rates of at maximum 500 k/h or 400 K/h have proven appropriate. Preferred heating rates amount at maximum to 300 K/h, especially at maximum 250 K/h, but a heating rate of about 200 K/h has been shown to be especially suitable. With these heating rates the oven is brought to the desired tempering rates and accordingly tempered for an extended time interval. After finishing tempering cooling takes place with a cooling rate of at maximum 400 K/h, preferably at maximum 300 K/h to a temperature between 1370 K and 1070 K. Cooling rates of 200 K/h, especially at maximum 150 K/h, have proven to be appropriate up to this first temperature. A typical cooling rate to a temperature of preferably 1070 K to 670 K amounts to about 100 K/h. A typical first run cooling temperature at a desired cooling rate amounts to about 1070 K. Subsequently preferably cooling to room temperature occurs with the oven shut off. This sort of cooling usually takes from 12 to 48 hours, wherein 16 to 32 hours is preferred. A typical cooling time and/or rate amounts to 20 to 28 hours but about 24 hours is especially suitable.

When a multi-step polishing process occurs after the tempering according to the invention, the surface layer freed of defect locations by the tempering may not be completely worn away or removed. It has proven suitable that at most 15 Πm, preferably at most 10 Πm, are removed. Especially preferably the removal should not amount to more than 8 Πm and usually not more than 5 Πm.

The smoothed layers so obtained are then cleaned or washed in the usual manner, which occurs preferably under clean room conditions, like are established for example for clean room class 100 (ISO 14644-1/2 or FS 209E). See also www.particle.com/whitepapers_met/cleanroom%20standards.htm.

After that the substrate/supporting material and/or wafer is prepared for coating with semiconductor material, such as for example GaN, AlN, InGaN, AlGaN or InN. The coating of the wafer and/or carrier substrate occurs by commercial methods, for example a MOCVD coater, like that which can be obtained from AIXTRON AG, Aachen, Germany, or Veeco Instruments, In., Somerset, N.J., USA.

The invention also relates to the use of the carrier substrates or wafers obtained by the method according to the invention to manufacture electronic components and to the components themselves. The electronic components according to the invention are used to make HL lasers and especially for the manufacture of high intensity light emitting diodes, which are used in high temperature and high power applications (HEMT, HBT and SAW).

The invention will now be illustrated with the aid of the following examples, the details of which should not be construed as limiting the appended claims.

### EXAMPLES

As described in DE-A 103 06 801.5, a cylindrical sapphire crystal was drawn according to the Czochralski method along its c-axis. Highly purified raw materials with a total impurity content of multivalent metal oxides, like Fe oxide, Ti oxide and Cr oxide, of less than 50 ppm were used. Furthermore test wafers of 5 cm diameter with a thickness of from 0.35 mm to 0.48 mm were sawed off of the crystal.

An additional reduction in thickness of about 0.05 mm±0.02 mm occurred in later processing steps, such as polishing and lapping. After lapping the test wafer so obtained was tempered in a standard tempering oven equipped with Super edge heating elements and with a mullite lining manufactured by the firm NABER, Lilienthal, Germany. The oxygen partial pressure of the oven atmosphere was 10⁻² mbar.

The wafer was placed in a tightly sealed box made from Iridium or Pt alloy, standing vertically in a guide frame made from stretched iridium or platinum wire. The wafer was then heated with a heating rate of 200 K/h to a desired temperature between 1770 K and 2070 K. This temperature was maintained for four hours. After that the wafer was cooled with a cooling rate of 100 K/h to 1070 K. The cooling to room temperature occurred in a time interval of about 24 hours with the oven turned off. In the present example the test wafer was tempered after the first mechanical working process, i.e. the lapping, to a wafer thickness of about 0.34 to 0.36 mm and finally to a final thickness of 0.33 mm. It was subsequently washed subjected to an after-cleaning under clean room conditions (clean room class 100). Then packaged for shipping “epi ready” (epitaxy ready), i.e. suitable directly for the epitaxy process of the user without further after-processing steps.

This process was repeated at tempering temperatures of 1770 K to 2070 K changed in 50 K steps. Each wafer so obtained was subsequently further processing with a commercial MOCVD coating apparatus of the firm AIXTRON AG, Aachen, Germany. Of course during the processing a 25 nm thick GaN nucleation layer was applied to the sapphire crystal substrate and, on that nucleation layer, a 2000 nm thick GaN layer and then a 1500 nm thick GaN:Si layer as n-layer were applied. Moreover a thin InₓGaᵢ₋ₓN SQW layer followed and on that a 60 nm thick Al_{0.1}Ga_{0.9}N:Mg layer was applied, which was covered by a 200 nm thick GaN:Mg layer and which acts as the p-side of a diode. The layers of the diodes so obtained were subsequently observed under 200-fold magnification and the number of pits per cm² was determined. The results are shown in the following Table I.

TABLE I
DIODE DEFECTS, PITS/cm², AS A FUNCTION OF
TEMPERING TEMPERATURE

| Temperature Level After | Number of |
|---|---|
| Lapping/Grinding, K | Pits/cm² |
| 1770 | 4 × 10⁵ |
| 1820 | 8 × 10⁴ |
| 1870 | 9 × 10² |
| 1920 | 2 × 10² |
| 1970 | sporadic |
| 2020 | very sporadic |
| 2070 | undetectable |

The disclosure in German Patent Application 10 2004 010 377.1 of Mar. 3, 2004 is incorporated here by reference. This German Patent Application describes the invention described hereinabove and claimed in the claims appended hereinbelow and provides the basis for a claim of priority for the instant invention under 35 U.S.C. 119.

While the invention has been illustrated and described as embodied in a method for making substrate wafers for low-defect semiconductor components, components obtained thereby and their use, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

1. A method of making a substrate wafer for a low-defect semiconductor component, said method comprising the steps of:
a) forming a single crystal having a [0001] surface perpendicular to a c-axis thereof;
b) subdividing said single crystal into at least one thin disk with at least one disk surface to be coated;
c) smoothing said at least one disk surface; and
d) tempering the at least one thin disk at a temperature above 1770 K.

2. The method as defined in claim 1, wherein the tempering is performed in an atmosphere with a reduced oxygen partial pressure.

3. The method as defined in claim 1, wherein the tempering occurs in a dust-poor environment.

4. The method as defined in claim 1, wherein the tempering occurs for at least 10 minutes at said temperature above 1770 K.

5. The method as defined in claim 1, wherein said single crystal is an Al₂O₃ single crystal with a hexagonal lattice structure.

6. The method as defined in claim 1, wherein the single crystal is subdivided on a plane, which extends perpendicular to a crystallographic axis.

7. The method as defined in claim 1, wherein the at least one thin disk has a thickness less than 2 mm.

8. A substrate wafer for a defect-free semiconductor component, wherein said substrate wafer is made by a method comprising the steps of:
a) forming a single crystal having a [0001] surface perpendicular to a c-axis thereof;
b) subdividing said single crystal into at least one thin disk with at least one disk surface to be coated;
c) smoothing said at least one disk surface; and
d) tempering the at least one thin disk at a temperature above 1770 K.

9. The substrate wafer as defined in claim 8, wherein said single crystal is an Al₂O₃ single crystal with a hexagonal lattice structure.

10. The substrate wafer as defined in claim 8, wherein the tempering occurs for at least 10 minutes at said temperature above 1770 K in a dust-poor atmosphere with a reduced oxygen partial pressure.

11. The substrate wafer as defined in claim 8, wherein the at least one thin disk has a thickness less than 2 mm.

12. An electronic component for lasers and high intensity light emitting diodes for high temperature and high energy applications, said electronic component being made from the substrate wafer as defined in claim 8.

13. An electronic semiconductor component comprising a substrate and one or more layers of semiconductor material placed one above the other on the substrate, said semiconductor component being obtained by a method comprising making a single crystal, subdividing the single crystal into a plurality of thin disks each with at least one disk surface to be coated, smoothing the at least one disk surface of the disks, the smoothing including lapping and/or grinding and polishing, tempering the disks at a temperature above 1770 K prior to a final polishing and coating of the at least one disk surface of the disks and then performing the polishing and the coating of the at least one disk surface.

14. The electronic semiconductor component as defined in claim 13, wherein said single crystal is an Al₂O₃ single crystal with a hexagonal lattice structure.

15. The electronic semiconductor component as defined in claim 13, wherein the thin disks each have a thickness less than 2 mm.
